(19) United States
(12) Patent Application Publication
(10) Pub. No.: US 2024/0246199 A1
(43) Pub. Date: Jul. 25, 2024

(54) VACUUM TABLE FOR WARPED PANELS

(71) Applicant: Orbotech Ltd., Yavne (IL)

(72) Inventors: Tal Goichman, Kiryat Ono (IL); Eyal Zalewski, Tel Aviv (IL)

(21) Appl. No.: 18/158,577

(22) Filed: Jan. 24, 2023

(51) Int. Cl. B25B 11/00; B21D 1/00

(52) U.S. Cl. CPC B25B 11/005; B21D 1/00

(57) ABSTRACT

The vacuum table includes a vacuum plate having openings on a top surface, a plurality of suction cups disposed on the top surface of the vacuum plate and having a bellows shape, and at least one vacuum source in fluid communication with the openings of the vacuum plate and the plurality of suction cups. The plurality of suction cups protrude from the top surface of the vacuum plate in an uncompressed state and are substantially coplanar with the top surface of the vacuum plate in a compressed state. The at least one vacuum source is configured to apply negative pressure to compress the plurality of suction cups into the compressed state.

### FIELD OF THE DISCLOSURE

This disclosure relates to methods of flattening a substrate and, more particularly, to using a vacuum table to flatten a substrate.

### BACKGROUND OF THE DISCLOSURE

Evolution of the semiconductor manufacturing industry is placing greater demands on yield management and, in particular, on metrology and inspection systems. Critical dimensions continue to shrink, yet the industry needs to decrease time for achieving high-yield, high-value production. Minimizing the total time from detecting a yield problem to fixing it determines the return-on-investment for a semiconductor manufacturer.

Fabricating semiconductor devices, such as logic and memory devices, typically includes processing a semiconductor wafer using a large number of fabrication processes to form various features and multiple levels of the semiconductor devices. For example, lithography is a semiconductor fabrication process that involves transferring a pattern from a reticle to a photoresist arranged on a semiconductor wafer. Additional examples of semiconductor fabrication processes include, but are not limited to, chemical-mechanical polishing (CMP), etch, deposition, and ion implantation. An arrangement of multiple semiconductor devices fabricated on a single semiconductor wafer may be separated into individual semiconductor devices.

Flattening may be required during a glass panel or other substrate fabrication process before further processes can be performed on the glass panel or other substrate. For example, it can be challenging to image a substrate if it is not flat. The focus will need to be constantly adjusted across a wide range of values if the substrate is warped, which can impede or even prevent effective inspection or metrology of the substrate. In order to flatten a substrate, a high vacuum flow may be applied to the substrate with a vacuum table. However, existing vacuum tables fail to adequately flatten the edges of warped panels. To address this issue, clamping devices can be used to push down on the edges of the panel. However, this carries a risk of damaging the active area of the panel due to contact stresses near the clamps. Clamps and other protrusions above the substrate also take up valuable space that is limited by the location of optical components. Each of these methods increase the complexity of the vacuum table and the maintenance demand of the fabrication process.

Therefore, what is needed is a vacuum table that is capable flattening heavily warped substrates and is simple to manufacture.

### BRIEF SUMMARY OF THE DISCLOSURE

An embodiment of the present disclosure provides a vacuum table comprising a vacuum plate having openings on a top surface, a plurality of suction cups disposed on the top surface of the vacuum plate and having a bellows shape, and at least one vacuum source in fluid communication with the openings of the vacuum plate and the plurality of suction cups. The openings may be defined between surface features on the top surface of vacuum plate. The plurality of suction cups may protrude from the top surface of the vacuum plate in an uncompressed state and may be substantially coplanar with the top surface of the vacuum plate in a compressed state. The at least one vacuum source may be configured to apply negative pressure to compress the plurality of suction cups into the compressed state.

According to an embodiment of the present disclosure, the vacuum table may further comprise a gasket disposed on the top surface of the vacuum plate at the perimeter of the vacuum plate. The gasket may be disposed in a sealing groove on the top surface of the vacuum plate and may protrude from the top surface of the vacuum plate. The gasket may protrude 200-500 microns from the top surface of the vacuum plate.

According to an embodiment of the present disclosure, the plurality of suction cups protrude at least 6 mm from the top surface of the vacuum plate in the uncompressed state.

According to an embodiment of the present disclosure, the plurality of suction cups may comprise a first set of suction cups arranged proximal to edges of the top surface of the vacuum plate, and a second set of suction cups arranged proximal to corners of the top surface of the vacuum plate. The first set of suction cups may be arranged parallel to each edge of the top surface of the vacuum plate. The second set of suction cups may be arranged radially symmetrical in the corners of the top surface of the vacuum plate.

According to an embodiment of the present disclosure, the at least one vacuum source may comprise a first vacuum source in fluid communication with the openings of the vacuum plate, and a second vacuum source in fluid communication with the plurality of suction cups. The second vacuum source may be configured to apply negative pressure to compress the plurality of suction cups into the compressed state. The openings may be connected to a primary distribution channel in the vacuum plate, and the first vacuum source may be in fluid communication with the openings via the primary distribution channel. The plurality of suction cups may be connected to a secondary distribution channel in the vacuum plate, and the second vacuum source may be in fluid communication with the secondary distribution channel.

Another embodiment of the present disclosure provides a method of flattening a substrate. The method may comprise providing a vacuum table. The vacuum table may comprise a vacuum plate having openings on a top surface, a plurality of suction cups disposed on the top surface of the vacuum plate and having a bellows shape, and at least one vacuum source in fluid communication with the openings of the vacuum plate and the plurality of suction cups. The plurality of suction cups may protrude from the top surface of the vacuum plate in an uncompressed state and may be substantially coplanar with the top surface of the vacuum plate in a compressed state.

The method may further comprise disposing the substrate on the top surface of the vacuum plate in contact with the plurality of suction cups, and controlling the at least one vacuum source to apply negative pressure in a space between the substrate and the top surface of the vacuum plate and in a space between the substrate and the plurality of suction cups, thereby compressing the plurality of suction cups into the compressed state and flattening the substrate against at least part of the top surface of the vacuum plate.

According to an embodiment of the present disclosure, the vacuum table may further comprise a gasket disposed on the top surface of the vacuum plate at the perimeter of the vacuum plate, which at least partially seals the space between the substrate and the top surface of the vacuum plate.

According to an embodiment of the present disclosure, the substrate disposed on the top surface of the vacuum plate may be warped such that there is a deflection up to 6 mm, and by flattening the substrate against at least part of the top surface of the top plate, the deflection may be reduced to substantially 0 mm.

Another embodiment of the present disclosure provides a vacuum table comprising a vacuum plate having openings on a top surface, a gasket disposed on the top surface of the vacuum plate at the perimeter of the vacuum plate, and a vacuum source in fluid communication with the openings of the vacuum plate. The gasket may protrude from the top surface of the vacuum plate in an uncompressed state, and the vacuum source may be configured to apply negative pressure to compress the gasket into a compressed state.

According to an embodiment of the present disclosure, in the uncompressed state, the gasket may protrude at least 6 mm from the top surface of the vacuum plate.

According to an embodiment of the present disclosure, the gasket may protrude at an angle away from the top surface of the vacuum plate. The angle may be 45 degrees.

According to an embodiment of the present disclosure, the gasket may have a bellows shape.

Another embodiment of the present disclosure provides a method of flattening a substrate. The method may comprise providing a vacuum table. The vacuum table may comprise a vacuum plate having openings on a top surface, a gasket disposed on the top surface of the vacuum plate at the perimeter of the vacuum plate, and a vacuum source in fluid communication with the openings of the vacuum plate. The gasket may protrude from the top surface of the vacuum plate in an uncompressed state, and the vacuum source may be configured to apply negative pressure to compress the gasket into a compressed state.

The method may further comprise disposing the substrate on the top surface of the vacuum plate in contact with the gasket, and controlling the vacuum source to apply negative pressure in a space between the substrate and the top surface of the vacuum plate sealed by the gasket, thereby compressing the gasket into the compressed state and flattening the substrate against at least part of the top surface of the vacuum plate.

### DESCRIPTION OF THE DRAWINGS

For a fuller understanding of the nature and objects of the disclosure, reference should be made to the following detailed description taken in conjunction with the accompanying drawings, in which:

FIG. 1 is a cross-sectional view of a vacuum table according to an embodiment of the present disclosure;

FIG. 2 is another cross-sectional view of the vacuum table of FIG. 1;

FIG. 3 is a top view of the vacuum table of FIG. 1;

FIG. 4 is a flowchart of a method of an embodiment of the present disclosure;

FIG. 5 is a cross-sectional view of a vacuum table according to another embodiment of the present disclosure;

FIG. 6 is another cross-sectional view of the vacuum table of FIG. 5;

FIG. 7 is a top view of the vacuum table of FIG. 5;

FIG. 8 is a cross-sectional view of a vacuum table according to another embodiment of the present disclosure;

FIG. 9 is another cross-sectional view of the vacuum table of FIG. 8; and

FIG. 10 is a flowchart of a method according to an embodiment of the present disclosure.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process, step, and electronic changes may be made without departing from the scope of the disclosure. Accordingly, the scope of the disclosure is defined only by reference to the appended claims.

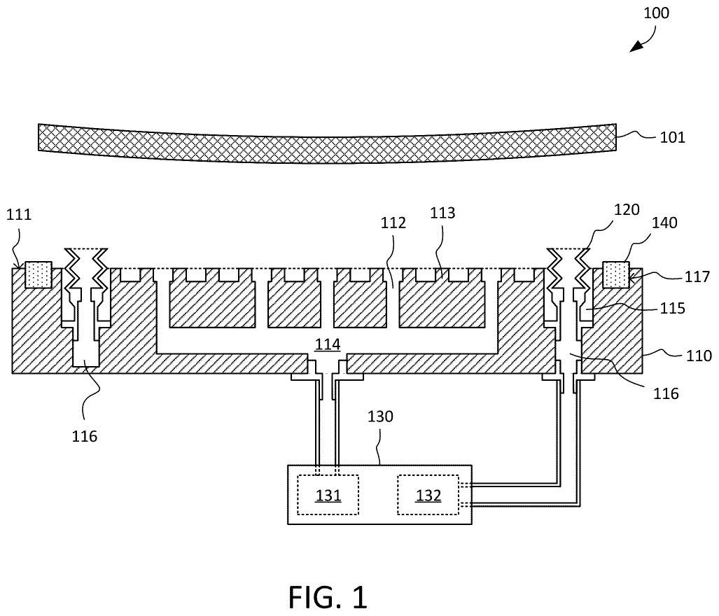

As shown in FIGS. 1-3, an embodiment of the present disclosure provides a vacuum table 100. The vacuum table 100 may comprise a vacuum plate 110. The vacuum plate 110 may be various shapes. For example, the vacuum plate 110 may be circular, rectangular, or any other polygonal shape. The length and width of the vacuum plate 110 may vary depending on the size of the substrate to be flattened. For example, for 510 mm by 515 mm substrates, the vacuum plate 110 may be greater than or equal to 510 mm by 515 mm. To flatten smaller substrates, a smaller vacuum plate 110 can be used.

The vacuum plate 110 may have a top surface 111, on which a substrate 101 sought to be flattened can be disposed. The substrate 101 may be an organic substrate panel, glass carrier panel, glass core panel, or other work piece sought to be flattened. The substrate 101 may have a thickness of 0.2 mm to 4 mm. The substrate 101 can be warped in a convex, concave, or other complex shapes like a saddle or potato chip, one example of which is shown in FIG. 1. The warp of the substrate 101 may be defined by the largest distance from the substrate 101 to a horizontal plane. The warp of the substrate 101 may be up to 6 mm, though other values are possible.

The top surface 111 of the vacuum plate 110 may have openings 112. The openings may be distributed across the top surface 111 of the vacuum plate 110, and may be connected by a primary distribution channel 114 inside the vacuum plate 110. The top surface 111 of the vacuum plate 110 may further comprise surface features 113. The surface features 113 may be depressions or projections in the top surface 111 of the vacuum plate. For example, the surface features 113 may be a network of grooves, a porous structure, or pin structures defined in the top surface 111 of the vacuum plate 110. In the embodiments shown in FIGS. 1-3, the surface features 113 are defined as a plurality of rectangular projections on the top surface 111 of the vacuum plate. For example, the rectangular projections may be 10 mm by 10 mm blocks or 5 mm by 5 mm blocks arranged in an array. The openings 112 may be defined in spaces between the rectangular projections. With the surfaces features 113, the openings 112 may communicate with more area of the substrate 101, as air can travel between the surface features 113.

The vacuum table 100 may further comprise a plurality of suction cups 120. The plurality of suction cups 120 may be disposed on the top surface 111 of the vacuum plate 110. For example, the plurality of suction cups 120 may be arranged at the perimeter of the top surface of the vacuum plate 111, radially outward from the openings 112 and surface features 113. Each of the plurality of suction cups 120 may be disposed in a respective recess 115 in the top surface 111 of the vacuum plate 110, and may connected by a secondary distribution channel 116 inside the vacuum plate 110. By being placed at the perimeter of the vacuum plate 110, the plurality of suction cups 120 may engage the edges of the substrate 101 for localized flattening.

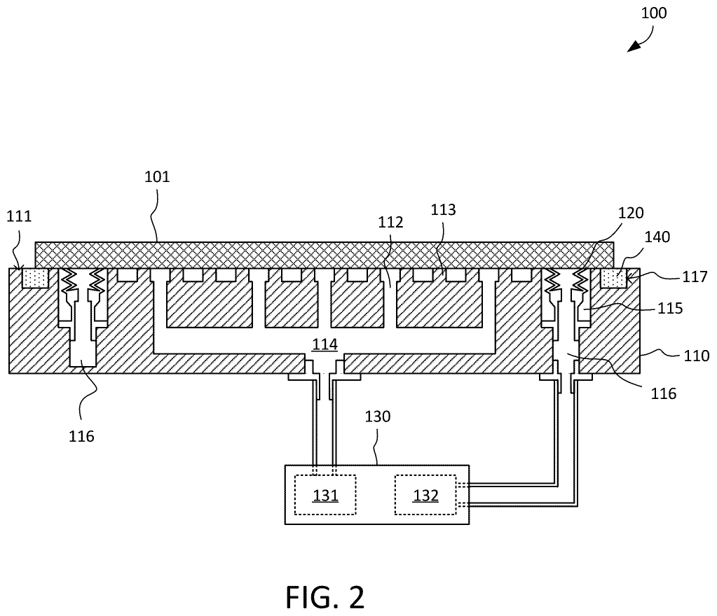

The plurality of suction cups 120 may have a bellows shape. In other words, the plurality of suction cups 120 may be compressible between an uncompressed state and a compressed state. In the uncompressed state (shown in FIG. 1), the plurality of suction cups 120 may protrude from the top surface 111 of the vacuum plate 110. For example, the plurality of suction cups 120 may protrude at least 6 mm from the top surface 111 of the vacuum plate 110 in the uncompressed state. Accordingly, the plurality of suction cups 120 may contact a surface of the substrate 101, even in the case of max warp of 6 mm. It should be understood that the plurality of suction cups 120 may protrude more or less from the top surface 111 of the vacuum plate 110 in order to flatten substrates 101 having more or less warp. In the compressed state (shown in FIG. 2), the plurality of suction cups 120 may be substantially coplanar with the top surface 111 of the vacuum plate 110. Accordingly, the substrate 101 may be flattened against the top surface 111 of the vacuum plate 110 when the plurality of suction cups 120 are in the compressed state.

In some embodiments, the plurality of suction cups 120 may have a rectangular shape. For example, the rectangular shape may be a rounded rectangular shape. Other round or polygonal shapes are possible.

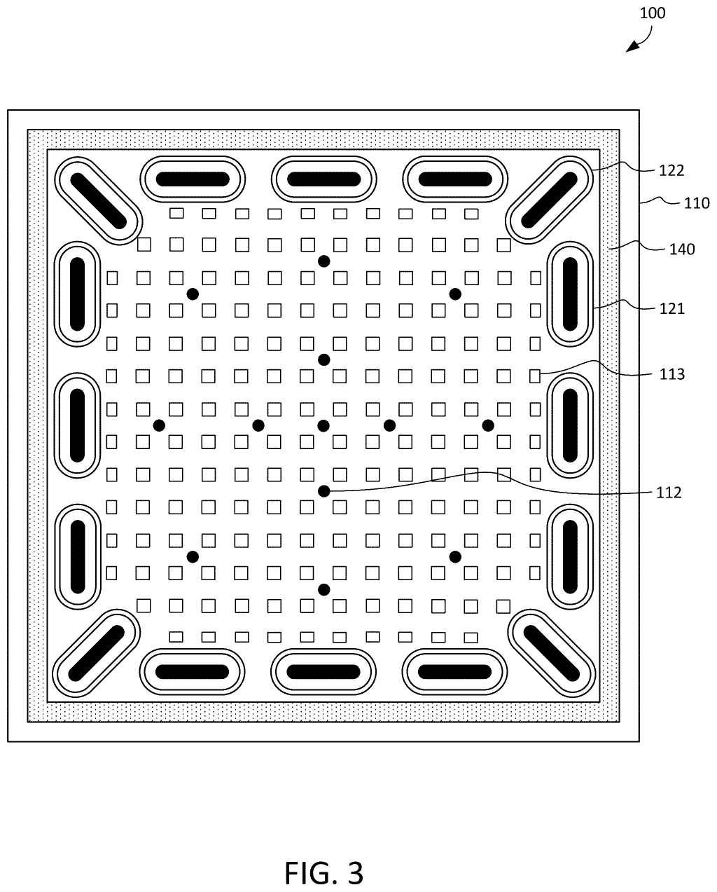

The plurality of suction cups 120 may comprise a first set of suction cups 121 and a second set of suction cups 122 (shown in FIG. 3). The first set of suction cups 121 may be arranged proximal to the edges of the top surface 111 of the vacuum plate 110. For example, the first set of suction cups 121 may be arranged parallel to the edges of the top surface 111 of the vacuum plate 110. Accordingly, the first set of suction cups 121 may be configured for localized flattening of the edges of the substrate 101. The second set of suction cups 122 may be arranged proximal to the corners of the top surface 111 of the vacuum plate 110. For example, the second set of suction cups 122 may be arranged radially symmetrical in the corners of the top surface 111 of the vacuum plate 110. Accordingly, the second set of suction cups 122 may be configured for localized flattening of the corners of the substrate 101. With the first set of suction cups 121 and the second set of suction cups 122, the plurality of suction cups 120 are arranged to address the portions of the substrate that may be more difficult to flatten.

In some embodiments, the first set of suction cups 121 and the second set of suction cups 122 may have the same shape. Alternatively, the first set of suction cups 121 and the second set of suction cups 122 may be different shapes, and may be selected for localized flattening of the edges and corners of the substrate, respectively.

The vacuum table 100 may further comprise at least one vacuum source 130. The at least one vacuum source 130 may be a vacuum pump with a power of 2-40 KPa. The at least one vacuum source 130 may be in fluid communication with the primary distribution channel 114 and the secondary distribution channel 116. Accordingly, the at least one vacuum source 130 may be configured to apply negative pressure through the openings 112 and the plurality of suction cups 120. When a substrate 101 is disposed on the top surface 111 of the vacuum plate 110 and the at least one vacuum source 130 applies negative pressure, the plurality of suction cups 120 may be compressed into the compressed state, thereby flattening the substrate 101 against the top surface 111 of the vacuum plate 110.

In some embodiments, the at least one vacuum source 130 may comprise a first vacuum source 131 and a second vacuum source 132. The first vacuum source 131 may be in fluid communication with the openings 112 via the primary distribution channel 114. The second vacuum source 132 may be in fluid communication with the plurality of suction cups 120 via the secondary distribution channel 116. Accordingly, the second vacuum source 132 may be configured to apply the negative pressure to compress the plurality of suction cups 120 into the compressed state, thereby flattening a substrate 101 against the top surface 111 of the vacuum plate 110. The first vacuum source 131 and the second vacuum source 132 may be operated simultaneously to apply negative pressure through the openings 112 and the plurality of suction cups 120. In some embodiments, the first vacuum source 131 may be operated before the second vacuum source 132. The first vacuum source 131 may be a vacuum pump with a power of 2-25 KPa, and the second vacuum source 132 may be a vacuum pump with a power of 18-40 KPa. The second vacuum source 132 may require less power to flatten the substrate 101, as the plurality of suction cups 120 seal with the substrate 101 and produce a static vacuum, which allows the plurality of suction cups 120 to collapse and apply a downward force to the substrate 101.

The vacuum table 100 may further comprise a gasket 140. The gasket 140 may be comprised of a flexible material, such as a soft silicone foam. The gasket 140 may be disposed in a sealing groove 117 on the top surface 111 of the vacuum plate 110. The sealing groove 117 may be disposed at the perimeter of the top surface 111 of the vacuum plate 110, radially outward from the plurality of suction cups 120. The gasket 140 may be configured to seal a space between the substrate 101 and the top surface 111 of the vacuum plate 110. Accordingly, the gasket 140 may reduce leakage and more efficiently flatten the substrate 101 when negative pressure is applied by the at least one vacuum source 130. The gasket 140 may protrude from the top surface 111 of the vacuum plate 110. For example, the gasket 140 may protrude 200-500 microns, but may not be coplanar with the top surface 111 of the vacuum plate 110. By protruding from the top surface 111, the gasket 140 may contact the substrate 101 to seal the space between the substrate 101 and the top surface 111 of the vacuum plate 110 after the plurality of suction cups 120 are collapsed into the compressed state. It should be understood that the gasket 140 may deform to be coplanar with the top surface 111 of the vacuum plate 110 to completely flatten the substrate 101 against the top surface 111 of the vacuum plate 110.

With the vacuum table 100 of the present disclosure, heavily warped substrates 101 can be flattened by applying negative pressure in the space between the substrate 101 and the top surface 111 of the vacuum plate 110 and in the space between the substrate 101 and the plurality of suction cups 120. The plurality of suction cups 120 may protrude to engage even the most warped portions of the substrate 101 and compress to completely flatten the substrate 101 against the top surface 111 of the vacuum table 110, and the arrangement of the suction cups 120 may be configured for localized flattening in areas of the substrate 101 that may be difficult to flatten.

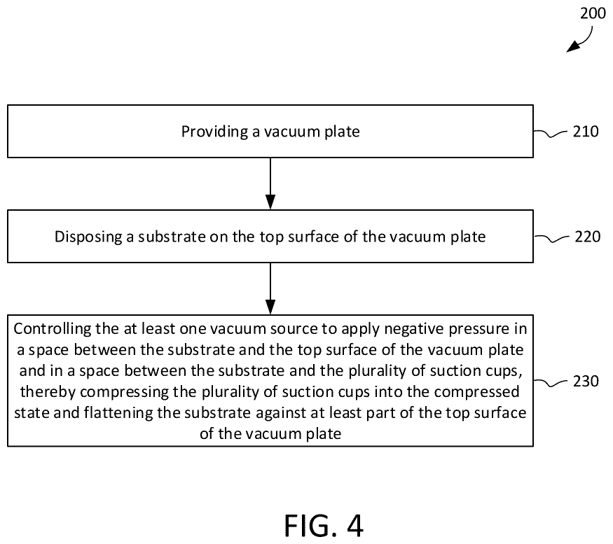

An embodiment of the present disclosure provides a method 200 of flattening a substrate. As shown in FIG. 4, the method 200 may comprise the following steps.

At step 210, a vacuum table is provided. The vacuum table may correspond to the vacuum table 100 described herein, the details of which are not repeated again here.

At step 220, a substrate is disposed on the top surface of the vacuum plate in contact with the plurality of suction cups. The substrate may be an organic substrate panel, glass carrier panel, glass core panel, or other work piece sought to be flattened. The substrate may have a thickness of 0.2 mm to 4 mm. The substrate can be warped in a convex, concave, or other complex shapes like a saddle or potato chip, one example of which is shown in FIG. 1. The warp of the substrate may be defined by the largest distance from the substrate to a horizontal plane. In some embodiments, the warp of the substrate may be up to 6 mm.

When the substrate is disposed on the top surface of the vacuum plate, the substrate may contact and at least partially compress the plurality of suction cups. Accordingly, the plurality of suction cups may be sealed with the substrate.

In some embodiments, the vacuum table further comprises a gasket disposed on the top surface of the vacuum plate at the perimeter of the vacuum plate. Thus, when the substrate is disposed on the top surface of the vacuum plate, the gasket at least partially seals the space between the substrate and the top surface of the vacuum plate.

At step 230, the at least one vacuum source is controlled to apply negative pressure in a space between the substrate and the top surface of the vacuum plate and in a space between the substrate and the plurality of suction cups. When the substrate is disposed on the top surface of the vacuum plate and the at least one vacuum source applies negative pressure, the plurality of suction cups may be compressed into the compressed state, thereby flattening the substrate against the top surface of the vacuum plate. By flattening the substrate against at least part of the top surface of the top plate, the warp may be reduced to substantially 0 mm.

With the method 200 of the present disclosure, heavily warped substrates can be flattened by applying negative pressure in the space between the substrate and the top surface of the vacuum plate and in the space between the substrate and the plurality of suction cups. The plurality of suction cups may protrude to engage even the most warped portions of the substrate and compress to completely flatten the substrate against the top surface of the vacuum table, and the arrangement of the suction cups may be configured for localized flattening in areas of the substrate that may be difficult to flatten.

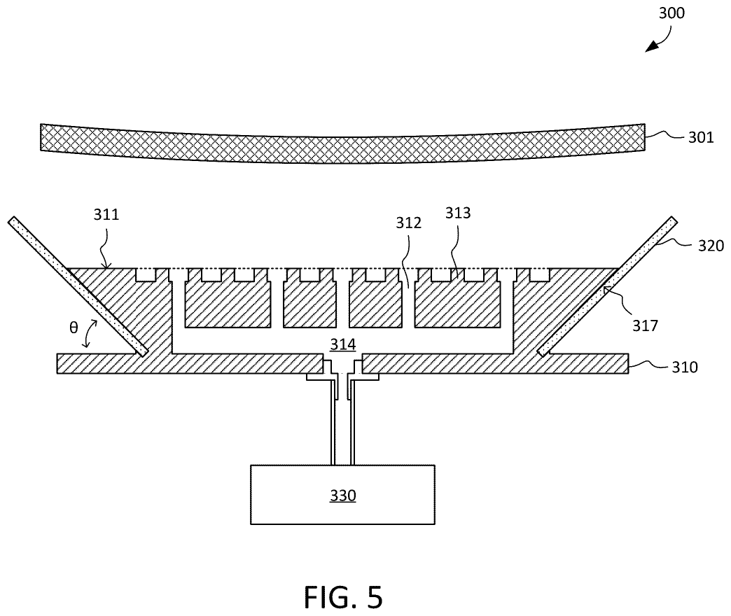

As shown in FIGS. 5-9, another embodiment of the present disclosure provides another vacuum table 300. The vacuum table 300 may comprise a vacuum plate 310. The vacuum plate 310 may be various shapes. For example, the vacuum plate 310 may be circular, rectangular, or any other polygonal shape. The length and width of the vacuum plate 310 may vary depending on the size of the substrate to be flattened. For example, for 510 mm by 515 mm substrates, the vacuum plate 310 may be greater than or equal to 510 mm by 515 mm. To flatten smaller substrates, a smaller vacuum plate 310 can be used.

The vacuum plate 310 may have a top surface 311, on which a substrate 301 sought to be flattened can be disposed. The substrate 301 may be an organic substrate panel, glass carrier panel, glass core panel, or other work piece sought to be flattened. The substrate 301 may have a thickness of 0.2 mm to 4 mm. The substrate 301 can be warped in a convex, concave, or other complex shapes like a saddle or potato chip, one example of which is shown in FIG. 5. The warp of the substrate 301 may be defined by the largest distance from the substrate 301 to a horizontal plane. The warp of the substrate 301 may be up to 6 mm, though other values are possible.

The top surface 311 of the vacuum plate 310 may have openings 312. The openings may be distributed across the top surface 311 of the vacuum plate 310, and may be connected by a primary distribution channel 314 inside the vacuum plate 310. The top surface 311 of the vacuum plate 310 may further comprise surface features 313. The surface features 313 may be depressions or projections in the top surface 311 of the vacuum plate. For example, the surface features 313 may be a network of grooves, a porous structure, or pin structures defined in the top surface 311 of the vacuum plate 310. In the embodiments shown in FIGS. 4 and 5, the surface features 313 are defined as a plurality of rectangular projections on the top surface 311 of the vacuum plate. For example, the rectangular projections may be 10 mm by 10 mm blocks or 5 mm by 5 mm blocks arranged in an array. The openings 312 may be defined in spaces between the rectangular projections. With the surfaces features 313, the openings 312 may communicate with more area of the substrate 301, as air can travel between the surface features 313.

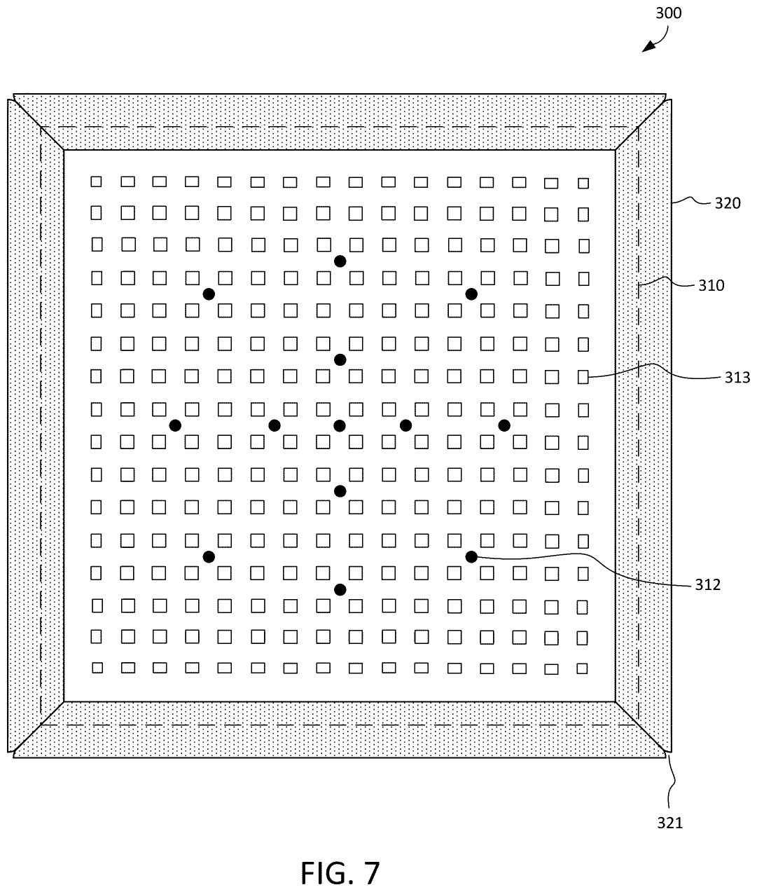

Referring to FIGS. 5-7, the vacuum table 300 may further comprise a gasket 320. The gasket 320 may be disposed on a sealing surface 317 on the side of the vacuum plate 310. The sealing surface 317 may be disposed around the perimeter of the top surface 311 of the vacuum plate 310, radially outward from the openings 312 and surface features 313. By being placed at the perimeter of the vacuum plate 310, the gasket 320 may engage the edges of the substrate 301 for localized flattening. Corners 321 of the gasket 320 may be notched and/or slit (as shown in FIG. 7) to more freely conform to the substrate 301.

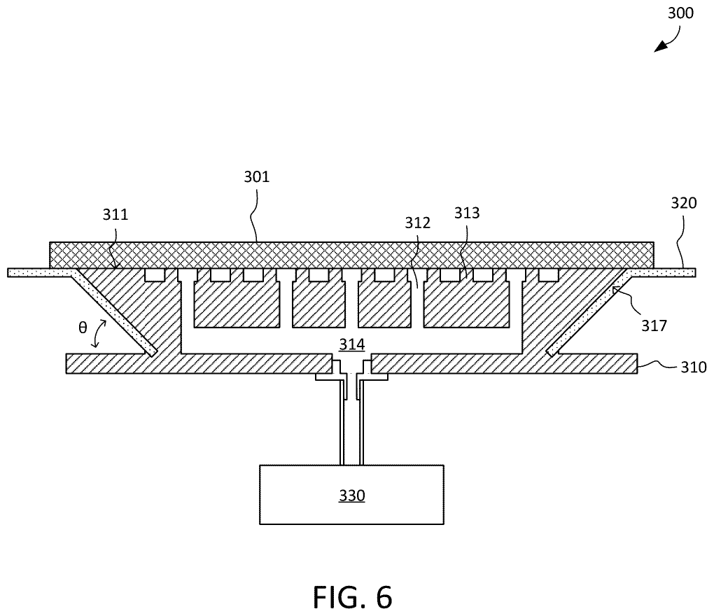

The gasket 320 may be comprised of a flexible material. For example, the gasket 320 may be a soft silicone foam. In other words, the gasket 320 may be compressible between an uncompressed state and a compressed state. In the uncompressed state, the gasket 320 may protrude from the top surface 311 of the vacuum plate 310. For example, the gasket 320 may protrude at least 6 mm from the top surface 311 of the vacuum plate 310 in the uncompressed state (shown in FIG. 5). Accordingly, the gasket 320 may contact a surface of the substrate 301, even in the case of max warp of 6 mm. It should be understood that the gasket 320 may protrude more or less from the top surface 311 of the vacuum plate 310 in order to flatten substrates 301 having more or less warp. In the compressed state (shown in FIG. 6), the gasket 320 may be substantially coplanar with the top surface 311 of the vacuum plate 310. The gasket 320 may maintain contact with the substrate 301 as it is compressed from the uncompressed state to the compressed state. Accordingly, the substrate 301 may be flattened against the top surface 311 of the vacuum plate 110 when the gasket 320 is in the compressed state. It should be understood that the gasket 320 may deform to be coplanar with the top surface 311 of the vacuum plate 310 to completely flatten the substrate 301 against the top surface 311 of the vacuum plate 310.

In some embodiments, the gasket 320 may protrude at an angle θ from the top surface 311 of the vacuum plate 310. For example, the angle θ may be 45 degrees. Accordingly, the gasket 320 may accommodate a larger range of substrates 301, as the substrate 301 can contact the angled surface of the gasket 340.

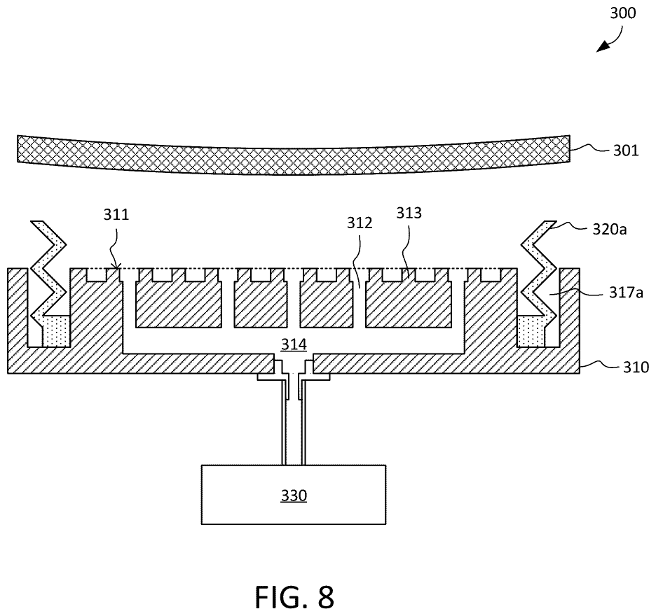

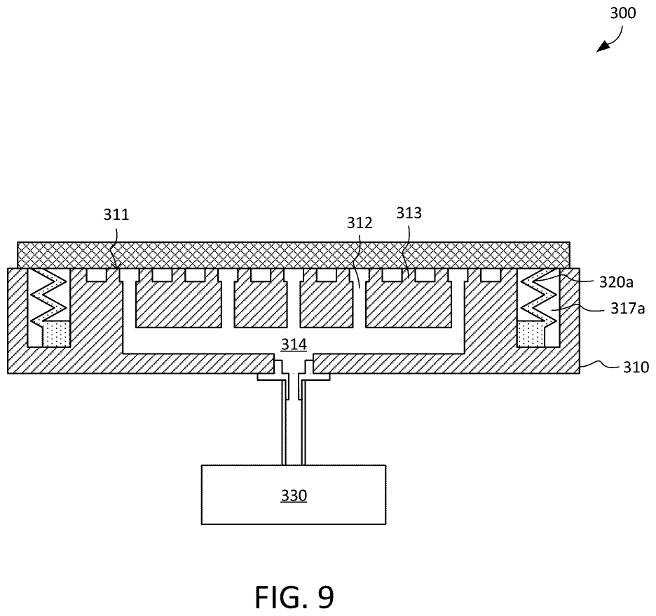

In some embodiments, the gasket 320 may be a bellows shaped gasket 320a, shown in FIGS. 8-9. The bellows shaped gasket 320a may be disposed in a sealing groove 317a on the top surface 311 of the vacuum plate 310. The bellows shaped gasket 320a is shown in the uncompressed sate in FIG. 8, and may compress downward into the compressed state (shown in FIG. 9) to flatten a substrate 301 against the top surface 311 of the vacuum plate 310.

The gasket 320 may be configured to seal a space between the substrate 301 and the top surface 311 of the vacuum plate 310. Accordingly, the gasket 320 may reduce leakage and more efficiently flatten the substrate 301 when negative pressure is applied by a vacuum source 330.

The vacuum table 300 may further comprise a vacuum source 330. The vacuum source 330 may be a vacuum pump with a power of 0.3-9.0 KPa. The vacuum source 330 may be in fluid communication with the primary distribution channel 314. Accordingly, the vacuum source 330 may be configured to apply negative pressure through the openings 312. When a substrate 301 is disposed on the top surface 311 of the vacuum plate 310 and the vacuum source 330 applies negative pressure, the gasket 320 may be compressed into the compressed state, thereby flattening the substrate 301 against the top surface 311 of the vacuum plate 310.

With the vacuum table 300 of the present disclosure, heavily warped substrates 301 can be flattened by applying negative pressure in the space between the substrate 301 and the top surface 311 of the vacuum plate 310, sealed by the gasket 320. The gasket 320 may protrude to engage even the most warped portions of the substrate 301 and compress to completely flatten the substrate 301 against the top surface 311 of the vacuum table 310, and by sealing the edges of the substrate 301, the gasket 320 may be configured to reduce leakage in areas of the substrate 301 that may be difficult to flatten.

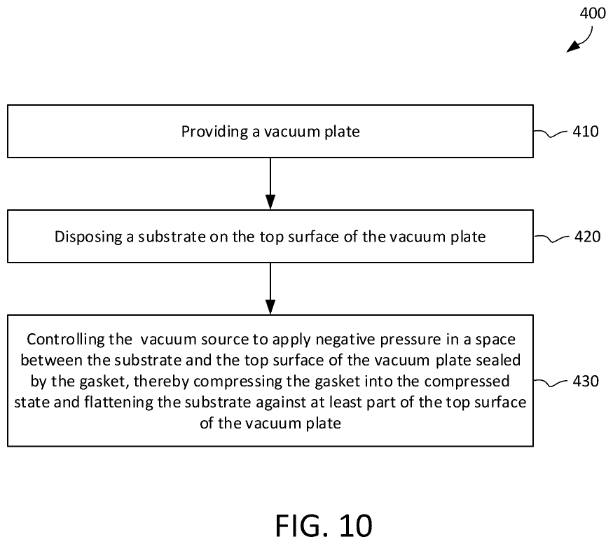

Another embodiment of the present disclosure provides a method 400 of flattening a substrate. As shown in FIG. 10, the method 400 may comprise the following steps.

At step 410, a vacuum table is provided. The vacuum table may correspond to the vacuum table 300 described herein, the details of which are not repeated again here.

At step 420, a substrate is disposed on the top surface of the vacuum plate in contact with the gasket. The substrate may be an organic substrate panel, glass carrier panel, glass core panel, or other work piece sought to be flattened. The substrate may have a thickness of 0.2 mm to 4 mm. The substrate can be warped in a convex, concave, or other complex shapes like a saddle or potato chip, one example of which is shown in FIG. 5. The warp of the substrate may be defined by the largest distance from the substrate to a horizontal plane. In some embodiments, the warp of the substrate may be up to 6 mm.

When the substrate is disposed on the top surface of the vacuum plate, the substrate may contact and at least partially compress the gasket. Accordingly, the gasket may at least partially seal the space between the substrate and the top surface of the vacuum plate.

At step 430, the vacuum source is controlled to apply negative pressure in a space between the substrate and the top surface of the substrate, sealed by the gasket. When the substrate is disposed on the top surface of the vacuum plate and the vacuum source applies negative pressure, the gasket may be compressed into the compressed state, thereby flattening the substrate against the top surface of the vacuum plate. By flattening the substrate against at least part of the top surface of the top plate, the warp may be reduced to substantially 0 mm.

With the method 400 of the present disclosure, heavily warped substrates can be flattened by applying negative pressure in the space between the substrate and the top surface of the vacuum plate, sealed by the gasket. The gasket may protrude to engage even the most warped portions of the substrate and compress to completely flatten the substrate against the top surface of the vacuum table, and by sealing the edges of the substrate, the gasket may be configured to reduce leakage in areas of the substrate that may be difficult to flatten.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A vacuum table comprising:
a vacuum plate having openings on a top surface;
a plurality of suction cups disposed on the top surface of the vacuum plate and having a bellows shape, wherein the plurality of suction cups protrude from the top surface of the vacuum plate in an uncompressed state and are substantially coplanar with the top surface of the vacuum plate in a compressed state; and
at least one vacuum source in fluid communication with the openings of the vacuum plate and the plurality of suction cups;
wherein the at least one vacuum source is configured to apply negative pressure to compress the plurality of suction cups into the compressed state.

2. The vacuum table of claim 1, further comprising:
a gasket disposed on the top surface of the vacuum plate at the perimeter of the vacuum plate.

3. The vacuum table of claim 2, wherein the gasket is disposed in a sealing groove on the top surface of the vacuum plate and protrudes from the top surface of the vacuum plate.

4. The vacuum table of claim 3, wherein the gasket protrudes 200-500 microns from the top surface of the vacuum plate.

5. The vacuum table of claim 1, wherein the plurality of suction cups protrude at least 6 mm from the top surface of the vacuum plate in the uncompressed state.

6. The vacuum table of claim 1, wherein the plurality of suction cups comprises:
a first set of suction cups arranged proximal to edges of the top surface of the vacuum plate; and
a second set of suction cups arranged proximal to corners of the top surface of the vacuum plate.

7. The vacuum table of claim 6, wherein the first set of suction cups are arranged parallel to each edge of the top surface of the vacuum plate.

8. The vacuum table of claim 6, wherein the second set of suction cups are arranged radially symmetrical in the corners of the top surface of the vacuum plate.

9. The vacuum table of claim 1, wherein the at least one vacuum source comprises:
a first vacuum source in fluid communication with the openings of the vacuum plate; and
a second vacuum source in fluid communication with the plurality of suction cups;
wherein the second vacuum source is configured to apply negative pressure to compress the plurality of suction cups into the compressed state.

10. The vacuum table of claim 9, wherein the openings are connected to a primary distribution channel in the vacuum plate, and the first vacuum source is in fluid communication with the openings via the primary distribution channel.

11. The vacuum table of claim 9, wherein the plurality of suction cups are connected to a secondary distribution channel in the vacuum plate, and the second vacuum source is in fluid communication with the secondary distribution channel.

12. The vacuum table of claim 1, wherein the openings are defined between surface features on the top surface of vacuum plate.

13. A method of flattening a substrate, comprising:
providing a vacuum table, comprising:
a vacuum plate having openings on a top surface;
a plurality of suction cups disposed on the top surface of the vacuum plate and having a bellows shape, wherein the plurality of suction cups protrude from the top surface of the vacuum plate in an uncompressed state and are substantially coplanar with the top surface of the vacuum plate in a compressed state; and
at least one vacuum source in fluid communication with the openings of the vacuum plate and the plurality of suction cups;
disposing the substrate on the top surface of the vacuum plate in contact with the plurality of suction cups; and
controlling the at least one vacuum source to apply negative pressure in a space between the substrate and the top surface of the vacuum plate and in a space between the substrate and the plurality of suction cups, thereby compressing the plurality of suction cups into the compressed state and flattening the substrate against at least part of the top surface of the vacuum plate.

14. The method of claim 13, wherein the vacuum table further comprises a gasket disposed on the top surface of the vacuum plate at the perimeter of the vacuum plate, which at least partially seals the space between the substrate and the top surface of the vacuum plate.

15. The method of claim 13, wherein the substrate disposed on the top surface of the vacuum plate is warped such that there is a deflection up to 6 mm, and by flattening the substrate against at least part of the top surface of the top plate, the deflection is reduced to substantially 0 mm.

16. A vacuum table comprising:
a vacuum plate having openings on a top surface;
a gasket disposed on the top surface of the vacuum plate at the perimeter of the vacuum plate; and
a vacuum source in fluid communication with the openings of the vacuum plate;
wherein the gasket protrudes from the top surface of the vacuum plate in an uncompressed state, and the vacuum source is configured to apply negative pressure to compress the gasket into a compressed state.

17. The vacuum table of claim 16, wherein in the uncompressed state, the gasket protrudes at least 6 mm from the top surface of the vacuum plate.

18. The vacuum table of claim 16, wherein the gasket protrudes at an angle away from the top surface of the vacuum plate.

19. The vacuum table of claim 18, wherein the angle is 45 degrees.

20. The vacuum table of claim 16, wherein the gasket has a bellows shape.
